(19) United States
(12) Patent Application Publication
(10) Pub. No.: US 2008/0038880 A1
(43) Pub. Date: Feb. 14, 2008

(54) Method of manufacturing a semiconductor device

(75) Inventors: Kikuo Okada, Saitama (JP); Tetsuya Okada, Kumagaya-shi (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD.; Sanyo Semiconductor Co., Ltd.

(21) Appl. No.: 11/882,883

(22) Filed: Aug. 6, 2007

(30) Foreign Application Priority Data
Aug. 8, 2006 (JP) 2006-215907

(51) Int. Cl. H01L 21/332

(52) U.S. Cl. 438/138; 257/E21.388

(57) ABSTRACT

There is the need to grind a semiconductor substrate from its back surface in order to thin a drift region for forming the NPT type IGBT. A collector region is then formed on the back surface of the semiconductor substrate by performing ion-implantation, a heat treatment and the like to the back surface of the semiconductor substrate of which the strength is weakened. This causes problems of warping the semiconductor substrate and the like. In a method of manufacturing a semiconductor device of the invention, the thickness of a drift region is previously adjusted by the thickness of an epitaxial layer. A collector region is then formed only by grinding a semiconductor substrate. In particular, using a semiconductor substrate containing a low concentration of impurity provides preferable characteristics for a high-speed switching element with a short turn-off time even when the collector region is thick.

### CROSS-REFERENCE OF THE INVENTION

This invention claims priority from Japanese Patent Application No. 2006-215907, the content of which is incorporated herein by reference in its entirety.

### BACKGROUND OF THE INVENTION

1. Field of the Invention

The invention relates to a method of manufacturing a semiconductor device, particularly a method of manufacturing an IGBT (Insulated Gate Bipolar Transistor) having suitable characteristics for a high-speed switching element.

2. Description of the Related Art

An insulated gate bipolar transistor is called IGBT, in which a fundamental cell combines the bipolar transistor and the MOSFET, forming a semiconductor device having both a low on-voltage characteristic of the former and a voltage drive characteristic of the latter.

FIG. 8 is a cross-sectional view of a conventional semiconductor device, showing an example of an NPT (non-punch-through) type IGBT.

A MOS structure is formed on a front surface side of an N⁻-type semiconductor substrate 101. In detail, P-type base regions 103 are selectively formed on a front surface of an N⁻-type drift region 102. Furthermore, N⁺-type emitter regions 104 are selectively formed on front surfaces of the base regions 103. Gate electrodes 106 are formed thereon with gate oxide films 105 interposed therebetween, covering all of the front surfaces of the base regions 103 between the emitter regions 104 and the drift region 102. Furthermore, the gate electrodes 106 are surrounded by insulation films 107, and an emitter electrode 108 is formed covering the insulation films 107 and being connected with the emitter regions 104.

A collector electrode 111 is formed on a back surface side of the semiconductor substrate 101, and a P⁺-type collector region 110 is formed being connected with the collector electrode 111.

The thickness of the drift region 102 is designed corresponding to a desired breakdown voltage. For realizing an IGBT having, for example, a breakdown voltage of 600V, the drift region 102 and the collector region 110 are designed to have thicknesses of about 90 μm and 1 μm, respectively.

With this structure, when a positive voltage is applied to the gate electrodes 106 in the state where a positive voltage is applied to the collector electrode 111, channels are formed in the base regions 103 under the gate electrodes 106, and thus electrons are supplied to the drift region 102 through these channels. When these electrons then reach the collector region 110 through the drift region 102, holes are supplied from the collector region 110 to the drift region 102, thereby achieving low on-resistance.

Since the amount of holes injected to the drift region 102 is small and the accumulation effect of minority carriers is low in the NPT type IGBT, when the voltage application is stopped, the holes accumulated in the drift region 102 are rapidly discharged through the collector electrode 111. Accordingly, this semiconductor device is used as a high-speed switching element or the like.

The relevant technology is described in the Japanese Patent Application Publication Nos. 2004-140101 and 2005-129652.

In the NPT type IGBT, generally, the thickness of the drift region 102 is designed corresponding to a desired breakdown voltage. For example, the drift region 102 is designed to have the thickness of about 90 μm for obtaining the breakdown voltage of 600V or the thickness of about 130 μm for obtaining the breakdown voltage of 1200V. The thickness of the drift region 102 is adjusted by grinding the semiconductor substrate 101 on its back side.

That is, the conventional process of manufacturing the NPT-type IGBT includes a process of grinding the semiconductor substrate 101 into the thickness of about 100 μm, and this leads to various problems.

Hereafter, the conventional process of manufacturing the semiconductor device will be partially described referring to FIGS. 8 to 12, and problems of the conventional method will be explained in detail.

First, as shown in FIG. 9, the N⁻-type semiconductor substrate 101 is prepared, and its front side surface is thermally oxidized to form an oxide film 105a. A gate electrode material 106a such as polysilicon or the like is then deposited on the oxide film 105a.

Then, as shown in FIG. 10, the gate oxide films 105 and the gate electrodes 106 are formed by performing photolithography and etching processes to the oxide film 105a and the gate electrode material 106a. A P-type impurity such as boron or the like is then ion-implanted into the substrate 101 using the gate electrodes 106 as a mask to form the P-type base regions 103. A photo resist pattern is selectively formed having openings in predetermined positions on the base regions 103, and then a high concentration of N-type impurity such as phosphorus or the like is ion-implanted therein to form the N⁺-type emitter regions 104.

As shown in FIG. 11, an insulation film is then formed over the front surface side of the semiconductor substrate 101, and photolithography and etching processes are performed thereto to form the insulation film 107 having openings in positions on the emitter regions 104. Then, Al or the like is embedded in the openings and covers the insulation film 107 to form the emitter electrode 108 connected with the emitter regions 104.

As shown in FIG. 12, the semiconductor substrate 101 is then ground from its back surface side to form the drift region 102 of about 90 μm so as to obtain a breakdown voltage of, for example, 600V.

Then, as shown in FIG. 8 described above, with the thickness and the strength being reduced, a P-type impurity such as boron or the like is ion-implanted into the back surface of the semiconductor substrate 101, and a heat treatment is performed thereto, thereby forming the P⁺-type collector region 110. Then, Al or the like is vapor-deposited on the back surface of the semiconductor substrate 101 to form the collector electrode 111 connected to the collector region 110.

As described above, the conventional method of manufacturing the NPT type IGBT needs the process of grinding the back surface of the semiconductor substrate 101 for thinning the drift region 102. The collector region 110 is formed on the semiconductor substrate 101 which is thinned by the grinding, and this easily causes serious problems such as warping the semiconductor substrate 101 by the ion implantation and the heat treatment.

In this respect, in the Japanese Patent Application Publication Nos. 2004-140101, 2005-129652 and the like, for solving the above problems, the semiconductor substrate 101 is strengthened with a supporting substrate or the like attached to its front surface and then its back surface is ground. The ion implantation and the heat treatment are then performed to the back surface with the supporting substrate being still attached to the front surface, thereby forming the collector region 110.

However, this method requires the supporting substrate itself and the processes of attaching and removing the supporting substrate, leading to an increase of the cost. There is also a problem in the mechanical strength of a completed device.

### SUMMARY OF THE INVENTION

The invention provides a method of manufacturing a semiconductor device, including: providing an epitaxial substrate including a first conductive type semiconductor substrate and a second conductive type epitaxial layer formed on the semiconductor substrate; forming a MOS structure on a front surface of the epitaxial layer; grinding a back surface of the semiconductor substrate; and forming a collector electrode on the back surface of the semiconductor substrate.

### BRIEF DESCRIPTION OF THE DRAWINGS

FIGS. 1 to 6 show processes of manufacturing a semiconductor device of the invention.

FIG. 7 shows a cross-sectional view of the semiconductor device of the invention.

FIG. 8 shows a cross-sectional view of a conventional semiconductor device.

FIGS. 9 to 12 show conventional processes of manufacturing a semiconductor device.

### DETAILED DESCRIPTION OF THE INVENTION

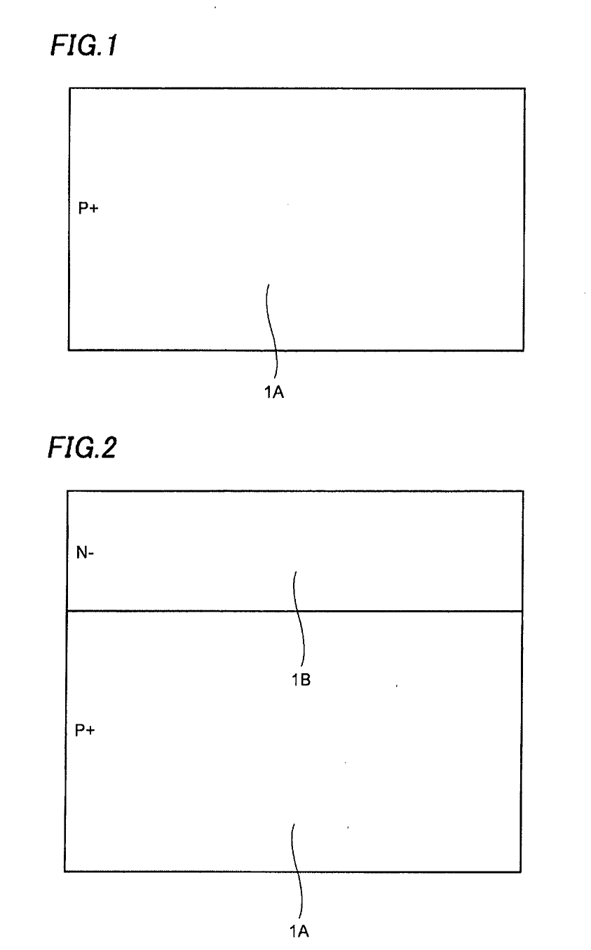

A method of manufacturing a semiconductor device of the invention will be described in detail referring to FIGS. 1 to 7. The description will be given on the method for an N-type conductive type IGBT as an example, although the method for a P-type conductive type IGBT is similar to this.

First, a P⁺-type semiconductor substrate 1A is prepared as shown in FIG. 1. The impurity concentration of the semiconductor substrate 1A is to be the impurity concentration of a collector region of the IGBT.

As shown in FIG. 2, an N⁻-type epitaxial layer 1B is formed by epitaxial growth on the front surface of the semiconductor substrate 1A. The epitaxial layer 1B is to serve as a drift region of the IGBT. Therefore, the thickness of the epitaxial layer 1B is designed corresponding to a desired breakdown voltage. For example, the epitaxial layer 1B is designed to have the thickness of about 90 μm for obtaining the breakdown voltage of 600V or the thickness of about 130 μm for obtaining the breakdown voltage of 1200V.

It is noted that an epitaxial substrate including the semiconductor substrate 1A and the epitaxial layer 1B is usually prepared and stored in advance.

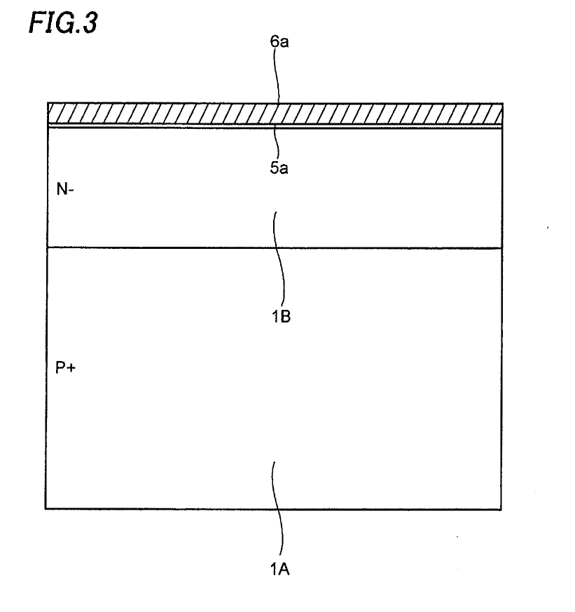

As shown in FIG. 3, the front surface of the epitaxial layer 1B is then thermally oxidized to form an oxide film 5a. A gate electrode material 6a is then deposited on the oxide film 5a. Polysilicon, polycide or the like is used as the gate electrode material 6a, for example.

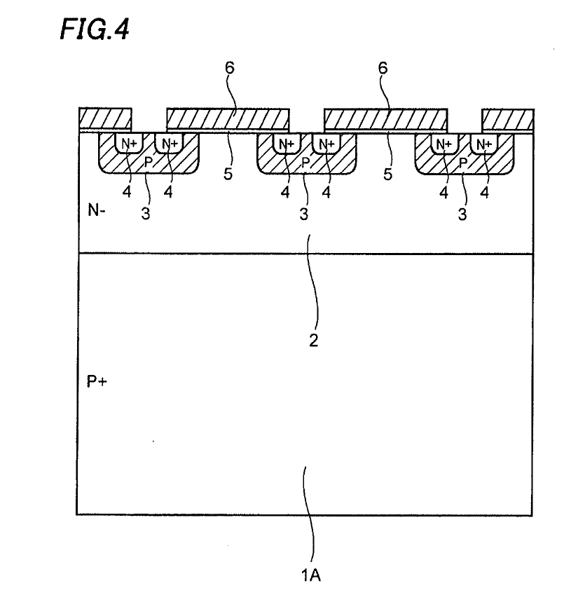

As shown in FIG. 4, gate oxide films 5 and gate electrodes 6 are formed by performing photolithography and etching processes to the oxide film 5a and the gate electrode material 6a. A P-type impurity such as boron or the like is ion-implanted into the epitaxial layer 1B using the gate electrodes 6 as a mask to form P⁻-type base regions 3. A photoresist pattern is then formed thereon having openings in predetermined positions on the base regions 3, and a high concentration of N-type impurity such as phosphorus or the like is ion-implanted therein to form N⁺-type emitter regions 4. The other region of the epitaxial layer 1B than the base regions 3 and the emitter regions 4 is defined as a drift region 2 hereafter.

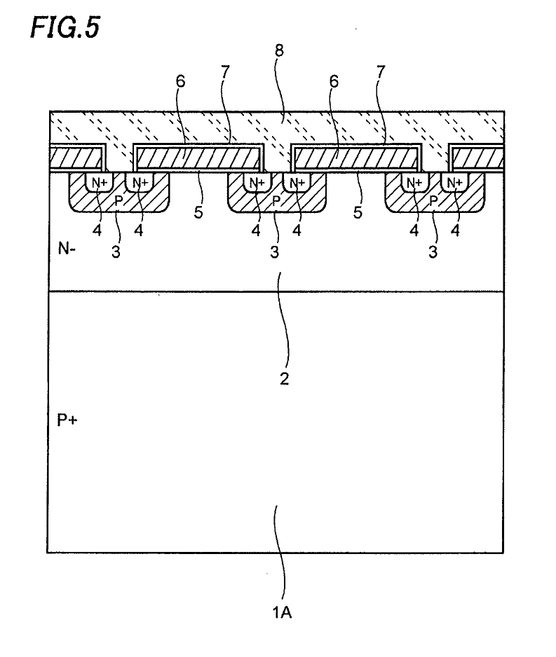

As shown in FIG. 5, an insulation film 7 is formed over the whole front surface of the epitaxial layer 1B including on the drift region 2. Photolithography and etching processes are performed to the insulation film 7 to form openings therein in positions on the emitter regions 4. An emitter electrode material such as Al, Cu, polysilicon or the like is embedded in the openings so as to be connected to the emitter regions 4, thereby forming an emitter electrode 8.

While a MOS structure is thus formed on the front surface of the epitaxial layer 1B through the above processes, the invention is applicable to the other structures without being limited to this MOS structure. For example, the invention may be applied to a vertical MOS transistor structure where a gate electrode is embedded in a trench groove although the gate electrode 6 is formed on the front surface of the epitaxial layer 1B in this embodiment.

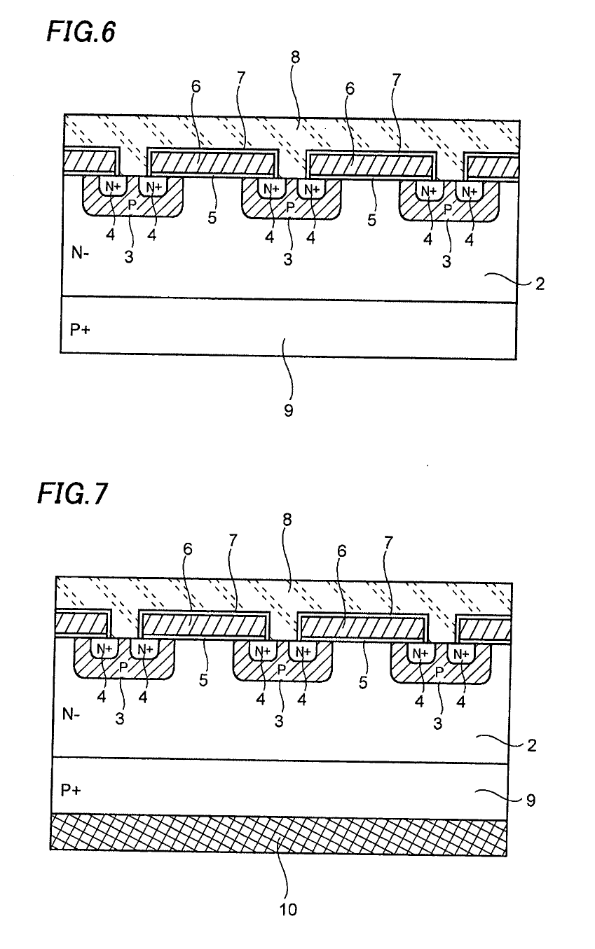

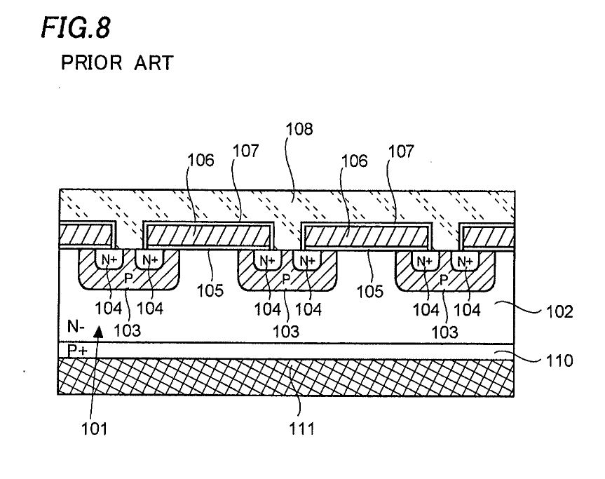

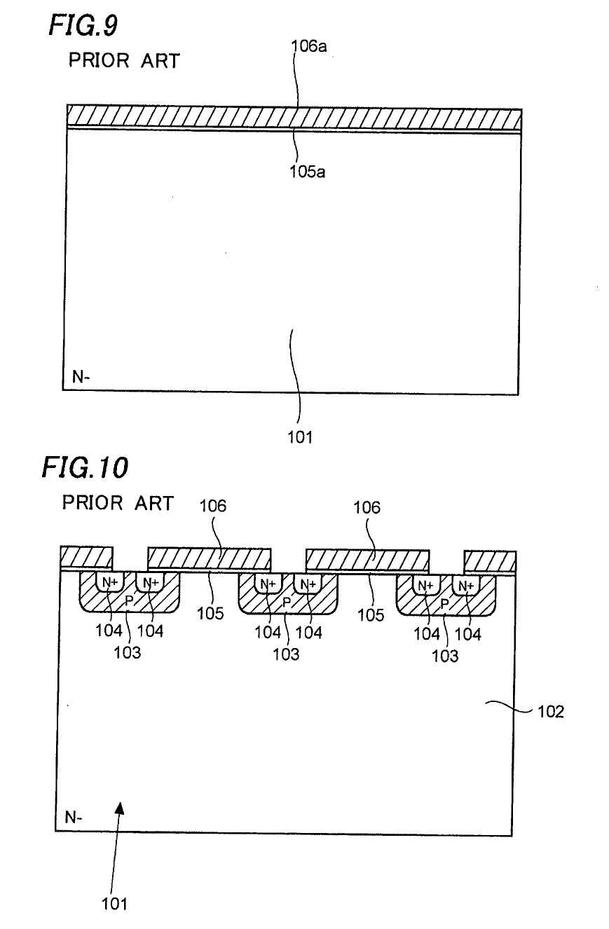

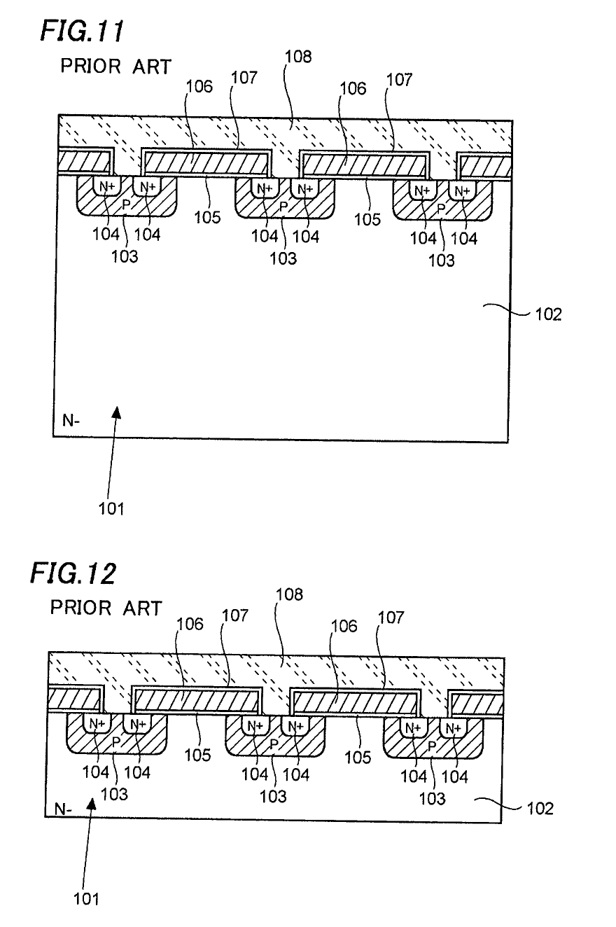

As shown in FIG. 6, the semiconductor substrate 1A is then ground from its back surface side. The semiconductor substrate 1A that undergoes this process is defined as a collector region 9. This process is particularly characteristic of this invention. In detail, in the semiconductor device formed by the manufacturing method of the invention, the charge amount of the collector region 9 is adjusted by the grinding thickness of the semiconductor substrate 1A. When on-resistance is taken more into account, the semiconductor substrate 1A is ground to have a large thickness for providing the collector region 9 with a large amount of charge. When a switching characteristic is taken more into account, the semiconductor substrate 1A is ground to have a small thickness for providing the collector region 9 with a small amount of charge. This method provides the charge amount equivalent to that of a collector region of a conventional NPT type IGBT. For example, for obtaining the charge amount equivalent to that of the conventional NPT type IGBT where the impurity concentration of the collector region is 1×10¹⁷/cm² and the thickness thereof is 1 μm, the semiconductor substrate 1A is preferably ground to provide the collector region 9 with a thickness of 100 μm when the semiconductor substrate 1A is a 50Ω substrate. That is, the thickness of the collector region 9 is adjustable by grinding the substrate 1A in the invention, and this provides freedom to determine the thickness of the collector region 9. Therefore, although the drift region 2 needs be thinned when the breakdown voltage is to be set low, the strength of the whole device is secured by increasing the thickness of the collector region 9 in the invention. In this respect, in the conventional device, it is difficult to control the thickness of the collector region 110 so as to adjust the strength since the collector region 110 is formed by ion-implantation. Therefore, the strength depends on the thickness of the drift region 102 and is not secured enough when the device is designed to have a low breakdown voltage.

When the switching characteristic is taken more into account, however, it seems that the collector region 9 does not contribute to securing the strength by the above method since the collector region 9 needs be thinned for obtaining a small amount of charge. However, when the switching characteristic is taken more into account, the reduction of the charge amount of the collector region 9 is achieved by reducing the impurity concentration of the semiconductor substrate 1A of the epitaxial substrate that is prepared first, even when the collector region 9 is thick. This means that the collector region 9 is allowed to increase its thickness for the reduction amount of the impurity concentration of the semiconductor substrate 1A which is initially prepared, and thus the mechanical strength is secured. This makes it possible to freely design the concentration and thickness of the collector region 9 corresponding to a required breakdown voltage, on-resistance, turn-off characteristic or the like.

As shown in FIG. 7, a collector electrode 10 is then formed on the back surface side of the semiconductor substrate 1A, being connected with the collector region 9. Cu or Al is used as the collector electrode 10, for example. Polysilicon may be also used as the collector electrode 10, and this is preferable since it has the same coefficient of thermal expansion as the semiconductor substrate 1A and the substrate is prevented from warping when the collector region 9 is thinned.

As described above, the collector region 9 is formed only by grinding the semiconductor substrate 1A in the method of manufacturing the semiconductor device of the invention, and thus the method does not require the ion implantation and the heat treatment that have been conventionally performed to the ground substrate with reduced mechanical strength. This prevents problems of warping the substrate and the like as have been conventionally seen.

Furthermore, since the adjustment of the charge amount of the collector region 9 is achieved by grinding the thickness of the substrate 1A, the desired on-resistance and switching characteristics are easily obtained. It is particularly important that the switching characteristic equivalent to that of the conventional NPT type IGBT is achieved.

Furthermore, even when the switching characteristic is taken more into account and thus the charge amount of the collector region 9 is to be reduced, the mechanical strength is kept stable since using the semiconductor substrate 1A containing a low concentration of impurity allows the collector region 9 to keep a predetermined thickness.

Hereafter, a description will be given on the operational principle of the semiconductor device of the invention referring to FIG. 7.

First, a detail description will be given on the operation when the device is turned on.

When a positive voltage is applied to the gate electrodes 6 in the state where a positive voltage is applied to the collector electrode 10, channels are formed in the base regions 3 under the gate electrodes 6. When electrons are supplied from these channels to the drift region 2 and flow into the collector region 9, holes are correspondingly supplied from the collector region 9 to the drift region 2, thereby reducing the on-resistance. It is noted that the on-resistance is adjustable by the thickness of the semiconductor substrate 1A in the invention. In detail, when the thickness of the collector region 9 is large, the holes supplied from the collector region 9 to the drift region 2 are increased and thus the on-resistance is reduced. On the contrary, when the thickness of the collector region 9 is small, the holes supplied from the collector region 9 to the drift region 2 are reduced and thus the on-resistance is increased.

Next, a detail description will be given on the operation when the device is turned off.

When the device is turned off, the holes accumulated in the drift region 2 are discharged from the collector electrode 10. As described above, the amount of holes accumulated in the drift region 2 is adjusted by the thickness of the collector region 9. In detail, when the thickness of the collector region 9 is large, the amount of holes supplied from the collector region 9 to the drift region 2 is increased and thus the on-resistance is reduced, but the time to discharge the holes is increased when the device is turned off and thus the switching characteristic is degraded. On the contrary, when the thickness of the collector region 9 is small, the amount of holes supplied from the collector region 9 to the drift region 2 is reduced and thus the on-resistance is increased, but the time to discharge the holes when the device is turned off is reduced and thus the switching characteristic is enhanced. Therefore, particularly when the function of high-speed switching is taken more into account, it is necessary to reduce the charge amount of the collector region 9. In this respect, although the charge amount of the collector region 9 is reduced when the semiconductor substrate 1A is largely ground to reduce the thickness of the collector region 9, the thickness of the collector region 9 for obtaining the switching characteristic equivalent to that of the NPT type IGBT is too thin to secure the mechanical strength. Therefore, when the switching characteristic equivalent to that of the NPT type IGBT is required, the impurity concentration of the semiconductor substrate 1A that is to be initially prepared is reduced. This realizes a small amount of charge even in the thick collector region 9, thereby securing the mechanical strength and providing the high-speed switching characteristic.

As described above, in the method of manufacturing the semiconductor device of the invention, the adjustment of the charge amount of the collector region 9 is achieved by the thickness and the impurity concentration of the semiconductor substrate 1A, the on-resistance and the switching characteristic are freely adjusted according to use.

In particular, it is necessary to thin the drift region 2 when the low breakdown voltage is required, but the strength of the device is secured since the thick collector region 9 is realized independent of the on-resistance and the switching characteristic in the invention.

In the method of manufacturing the semiconductor device of the invention, the collector region is formed only by the process of grinding the back surface of the semiconductor substrate. That is, in the invention, the collector region is formed by grinding the back surface of the semiconductor substrate, without the ion implantation and the heat treatment to the ground back surface of the semiconductor substrate as have been conventionally performed. This method prevents a wafer from cracking and does not require special equipment or the like.

Furthermore, the adjustment of the charge amount of the collector region is achieved by the grinding thickness of the semiconductor substrate. This easily provides a switching characteristic equivalent to that of the NPT type IGBT.

In particular, using a semiconductor substrate having low charge concentration provides the equivalent charge amount and the equivalent switching characteristic to those of the collector region of the conventional NPT-type IGBT, even when the collector region is thick. That is, the method of manufacturing the semiconductor device of the invention does not require much grinding of the back surface layer that affects the yield.

What is claimed is:

1. A method of manufacturing a semiconductor device, comprising:
providing an epitaxial substrate including a first conductive type semiconductor substrate and a second conductive type epitaxial layer formed on the semiconductor substrate;
forming a MOS structure on a front surface of the epitaxial layer;
grinding a back surface of the semiconductor substrate; and
forming a collector electrode on the back surface of the semiconductor substrate.

2. The method of claim 1, the step of forming the MOS structure comprising:
forming an oxide film on the front surface of the epitaxial layer;
depositing a gate electrode material on the oxide film;
forming a gate oxide film and a gate electrode by performing photolithography and etching processes to the oxide film and the gate electrode material;
forming a base region by implanting a first conductive type impurity using the gate electrode as a mask;
forming a resist having an opening on the base region;
forming an emitter region by implanting a second conductive type impurity using the resist as a mask;
forming an insulation film over the front surface of the epitaxial layer;
forming an opening in the insulation film on the emitter region by photolithography and etching processes; and
forming an emitter electrode in the opening formed in the insulation film.

3. The method of claim 1, wherein the semiconductor substrate is ground so that a total amount of first conductive type charge is equivalent to a total amount of first conductive type charge in a collector region of an NPT type IGBT.

4. The method of claim 1, wherein a thickness of the epitaxial layer is designed corresponding to a breakdown voltage.

5. The method of claim 2, wherein a thickness of the epitaxial layer is designed corresponding to a breakdown voltage

6. The method of claim 3, wherein a thickness of the epitaxial layer is designed corresponding to a breakdown voltage
